(19) United States
(12) Patent Application Publication
(10) Pub. No.: US 2026/0299720 A1
(43) Pub. Date: Oct. 1, 2026

(54) DISPLAY PANEL AND METHOD OF MANUFACTURING THE SAME, DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Ren Xiong, Beijing (CN); Xuan Luo, Beijing (CN); Fengping Wu, Beijing (CN); Yu Pan, Beijing (CN); Zhihui Wang, Beijing (CN); Lei Zhang, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 19/479,418

(22) PCT Filed: Jan. 22, 2025
(86) PCT No.: PCT/CN2025/074036

§ 371 Date: Oct. 28, 2025

(30) Foreign Application Priority Data
Feb. 21, 2024 (CN) 202410196155.0

(51) Int. Cl. G06F 3/041

(52) U.S. Cl. CPC G06F 3/04164; G06F 2203/04102; G06F 2203/04103

(57) ABSTRACT

Provided are a display panel, a manufacturing method thereof and a display device, related to the field of display technologies. The display panel includes: a display substrate having a display area, and a non-display area including a display terminal and a touch terminal, a display wire in the display area extends to a binding area of the display terminal; a touch layer on a light-emitting side of the display substrate and including a touch wire extending to a binding area of the touch terminal; a control circuit on the backlight side of the display substrate and including a display control module electrically connected to the display wires and a touch module electrically connected to the touch wire.

### CROSS-REFERENCE TO RELATED APPLICATION(S)

This application is a Section 371 National Stage Application of International Application No. PCT/CN2025/074036, filed on Jan. 22, 2025, which claims priority to Chinese Patent Application No. 202410196155.0, filed on Feb. 21, 2024, entitled “DISPLAY PANEL AND METHOD OF MANUFACTURING THE SAME, DISPLAY DEVICE”, the whole contents of which are incorporated herein by reference in their entireties.

### TECHNICAL FIELD

The present disclosure relates to the field of display technologies, and in particular, to a display panel a method of manufacturing a display panel, and a display device.

### BACKGROUND

In the modern communication industry, the demands for medium and large-sized display products such as TVs, tablet computers, notebook computers and automotive displays are increasing, and various display products are also developed to have a larger screen ratio. In the related art, the display wires of the medium and large-sized display products are usually bent to the back of the display products by means of COF (chip on film) bending, FPC (flexible printed circuit) bending, etc., so as to achieve normal display of the display products. However, the COF bending, the FPC bending, etc. inevitably lead to relatively large bezels of the display products, reducing the user's stickiness.

It should be noted that the information disclosed in the above background section is only used to enhance an understanding of the background of the present disclosure. Therefore, it may include information that does not constitute the related art known to those of ordinary skill in the art.

### SUMMARY

The objective of the present disclosure is to provide a display panel and a method of manufacturing a display panel, and a display device, capable of effectively improving the screen ratio of the medium and large sized display products and achieving narrow bezel.

According to an aspect of the present disclosure, a display panel is provided, including: a display substrate including a display area and a non-display area located at a periphery of the display area, the non-display area includes a display terminal and a touch terminal, each of the display terminal and the touch terminal includes a bending area and a binding area, the bending area is respectively connected to the display area and the binding area, the binding area is located on a backlight side of the display area after the bending area is bent, and the display area includes a display wire extending to the binding area of the display terminal; a touch layer located on a light emitting side of the display substrate and including a touch wire located in the display area and extending to the binding area of the touch terminal; and a control circuit located on the backlight side of the display substrate and including a display control module electrically connected to the display wire and a touch module electrically connected to the touch wire.

In the display panel according to any embodiment of the present disclosure, the non-display area includes one display terminal located on a side of the display area in a column direction; and the display terminal includes a plurality of binding areas located on a side of the bending area away from the display area, and each of the plurality of binding areas of the display terminal includes the display wire.

In the display panel according to any embodiment of the present disclosure, a width of the display terminal in a row direction is not less than 70 mm and not more than 600 mm.

In the display panel according to any embodiment of the present disclosure, the non-display area includes a plurality of display terminals located on a same side of the display area in a column direction and spaced apart in a row direction.

In the display panel according to any embodiment of the present disclosure, a distance between adjacent display terminals is greater than 5 mm.

In the display panel according to any embodiment of the present disclosure, the non-display area includes a first touch terminal located on a same side of the display area as the display terminal, and the first touch terminal is located on an outermost side of the display terminal in a row direction.

In the display panel according to any embodiment of the present disclosure, the first touch terminal is integrated with the adjacent display terminal.

In the display panel according to any embodiment of the present disclosure, the non-display area further includes a second touch terminal located on a side of the display area away from the display terminal.

In the display panel according to any embodiment of the present disclosure, the non-display area further includes a pair of third touch terminals respectively located on two sides of the display area in the row direction.

In the display panel according to any embodiment of the present disclosure, the non-display area includes a plurality of display terminals, and the plurality of display terminals include a first display terminal, a second display terminal and at least one third display terminal; and the first display terminal and the second display terminal are located on a same side of the display area in a column direction and spaced apart in a row direction; the at least one third display terminal is located on a side of the display area away from the first display terminal and spaced apart in the row direction, and each of the at least one third display terminal is located between the first display terminal and the second display terminal in the row direction.

In the display panel according to any embodiment of the present disclosure, a distance between the first display terminal and the second display terminal is not less than 30 mm.

In the display panel according to any embodiment of the present disclosure, the non-display area includes a pair of first touch terminals located on a same side of the display area as the at least one third display terminal, and the pair of first touch terminals are respectively located on two sides of the at least one third display terminal in the row direction.

In the display panel according to any embodiment of the present disclosure, the non-display area further includes a pair of third touch terminals respectively located on two sides of the display area in the row direction.

In the display panel according to any embodiment of the present disclosure, the control circuit further includes a first switching circuit and a second switching circuit; and the first switching circuit is respectively electrically connected to the display wire and the display control module, and the second switching circuit is respectively electrically connected to the touch wire and the touch module.

In the display panel according to any embodiment of the present disclosure, the display substrate includes a display film layer, a back adhesive layer and a protective layer sequentially stacked in a direction away from the touch layer; and at least a part of the protective layer is thinned in the bending area in a thickness direction, or a whole of the protective layer and the back adhesive layer is thinned in the bending area.

According to an aspect of the present disclosure, a method of manufacturing a display panel is provided, including: manufacturing a display substrate including a display area and a non-display area located at a periphery of the display area, the non-display area includes a display terminal and a touch terminal, each of the display terminal and the touch terminal includes a bending area and a binding area, the bending area is respectively connected to the display area and the binding area, and the display area includes a display wire extending to the binding area of the display terminal; manufacturing a touch layer on a light emitting side of the display substrate, the touch layer includes a touch wire extending to the binding area of the touch terminal; and providing a control circuit including a display control module and a touch module, the bending area is bent such that the binding area is located on a backlight side of the display area, and on the backlight side of the display substrate, the display control module is electrically connected to the display wire, and the touch module is electrically connected to the touch wire.

According to an aspect of the present disclosure, a display device is provided, including a control mainboard and the display panel according to any aspect described above, the display control module and the touch module are electrically connected to the control mainboard.

### BRIEF DESCRIPTION OF THE DRAWINGS

The accompanying drawings, which are incorporated into the specification and constitute a part of the present specification, illustrate embodiments consistent with the present disclosure and serve to explain principles of the present disclosure together with the specification. Obviously, the drawings in the following descriptions are only some embodiments of the present disclosure, and other drawings may be obtained by those of ordinary skill in the art according to these drawings without creative effort.

FIG. 1 is a schematic structural cross-sectional diagram of a display panel provided by the embodiments of the present disclosure.

FIG. 2 is a schematic top structural view of a display substrate provided by the embodiments of the present disclosure when unfolded.

FIG. 3 is a schematic top structural view of a display panel provided by the embodiments of the present disclosure when unfolded.

FIG. 4 is a schematic cross-sectional diagram of a display substrate provided by the embodiments of the present disclosure.

FIG. 5 is a schematic top structural view of another display substrate provided by the embodiments of the present disclosure when unfolded.

FIG. 6 is a schematic top structural view of yet another display substrate provided by the embodiments of the present disclosure when unfolded.

FIG. 7 is a schematic top structural view of yet another display panel provided by the embodiments of the present disclosure when unfolded.

FIG. 8 is a schematic top structural view of yet another display panel provided by the embodiments of the present disclosure when unfolded.

FIG. 9 is a schematic top structural view of another display panel provided by the embodiments of the present disclosure when unfolded.

FIG. 10 is a schematic bottom structural view of another display panel provided by the embodiments of the present disclosure after being bent.

FIG. 11 is a schematic bottom structural view of still another display panel provided by the embodiments of the present disclosure after being bent.

FIG. 12 is a schematic bottom structural view of still another display panel provided by the embodiments of the present disclosure after being bent.

### REFERENCE SIGNS

10. Display panel;
AA. Display area; BB. Non-display area; B1. Display terminal; B2. Touch terminal; B3. Bending area; B4. Binding area;
B11. First display terminal; B12. Second display terminal; B13. Third display terminal;
B21. First touch terminal; B22. Second touch terminal; B23. Third touch terminal;
11. Display substrate; 12. Touch layer; 13. Control circuit; 14. Polarizer layer; 15. Optical adhesive layer; 16. Cover plate; 17. Heat dissipation layer; 18. Support layer;
111. Display film layer; 112. Back adhesive layer; 113. Protective layer;
131. Display control module; 132. Touch module; 133. First switching circuit; 134. Second switching circuit.

### DETAILED DESCRIPTION OF EMBODIMENTS

Exemplary embodiments will now be described more fully with reference to the accompanying drawings. However, the exemplary embodiments may be embodied in various forms, and the present disclosure should not be understood as being limited to the embodiments set forth here. Rather, these embodiments are provided so that the present disclosure will be thorough and complete, and the concepts of the exemplary embodiments will be fully conveyed to those skilled in the art. The same reference signs in the drawings indicate the same or similar structures, and therefore the descriptions will be omitted. In addition, the drawings are only schematic illustrations of the present disclosure and are not necessarily drawn to scale.

Although relative terms such as “above” and “below” are used in the specification to describe a relative relationship of an assembly to another assembly in the drawings, these terms are used in the specification only for convenience, for example, according to the directions of the examples described in the drawings. It may be understood that if a device in a drawing is turned upside down, an assembly described as being “above” the device will become an assembly described as being “below” the device. When a structure is “on” another structure, it may refer to that the structure is integrally formed on the another structure, or that the structure is “directly” arranged on the another structure, or that the structure is “indirectly” arranged on the another structure through yet another structure.

The terms “a, “an”, “the”, “said” and “at least one” are used to indicate the existence of one or more elements/components/etc. The terms “include” and “have” are used to indicate an open-ended inclusion and refer to that there may be other elements/components, etc. in addition to the listed elements/components, etc. The terms “first”, “second”, “third”, etc. are only used as designations, rather than limiting the number of objects.

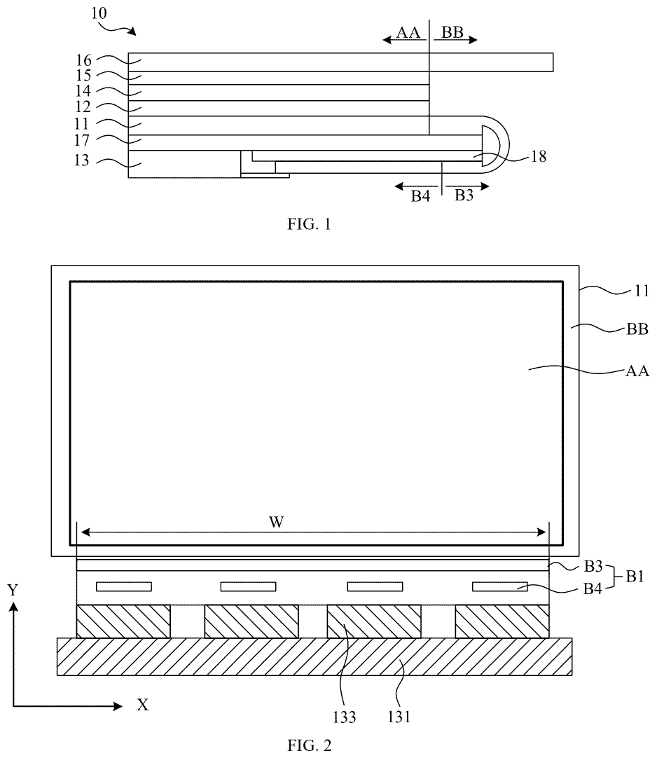

FIG. 1 schematically shows a schematic structural cross-sectional diagram of a display panel 10 provided by the embodiments of the present disclosure. FIG. 2 schematically shows a schematic top structural view of a display substrate 11 provided by the embodiments of the present disclosure before being folded. As shown in FIG. 1 and FIG. 2, the display panel 10 includes a display substrate 11 having a display area AA and a non-display area BB located at a periphery of the display area AA. The non-display area BB includes a display terminal B1 including a bending area B3 and a binding area B4. The bending area B3 is respectively connected to the display area AA and the binding area B4, and the binding area B4 is located on a backlight side of the display area AA after the bending area B3 is bent.

In the embodiments of the present disclosure, the display terminal B1 located in the non-display area BB is directly arranged on the display substrate 11 included in the display panel 10, so that the binding area B4 may be bent to the backlight side of the display area AA based on the bending area B3 on the display terminal B1 included in the display substrate 11, thereby reducing a bending radius of the display terminal B1, effectively reducing a bezel of the display panel 10 and achieving narrow bezel of the display panel 10.

The display area AA includes a display wire extending to the binding area B4 of the display terminal B1, so as to facilitate an electrical connection with a control circuit 13 and achieving image display in the display area AA.

In some embodiments, as shown in FIG. 1, the display panel 10 further includes a touch layer 12 located on a light emitting side of the display substrate 11.

The touch layer 12 includes a touch wire located in the display area AA, and the touch wire extends to the non-display area BB of the display substrate 11 and is electrically connected to the control circuit 13. In this way, a touch operation of the display panel 10 may be achieved with a cooperation of the touch wire and the control circuit 13.

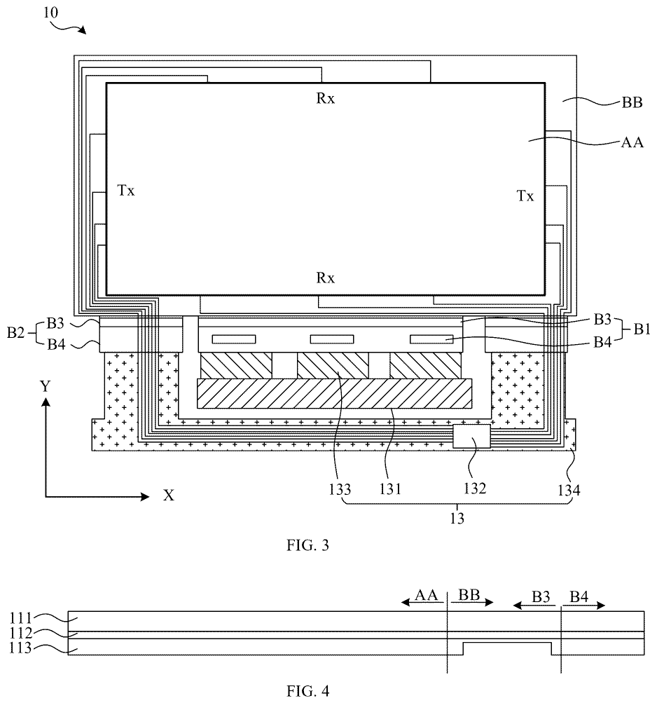

As shown in FIG. 3, the non-display area BB of the display panel 10 also includes a touch terminal B2, which has a same structure as the display terminal B1, that is, the touch terminal B2 also includes a bending area B3 and a binding area B4, so that the binding area B4 of the touch terminal B2 may be bent to the backlight side of the display area AA based on the bending area B3 on the touch terminal B2 included in the display substrate 11, thereby reducing a bending radius of the touch terminal B2, effectively reducing the bezel of the display panel 10 and achieving narrow bezel of the display panel 10.

In addition, as shown in FIG. 3, the touch wire includes a Tx wire (driving wire) and an Rx wire (receiving wire). The Tx wire and the Rx wire extend to the binding area B4 of the touch terminal B2 in the non-display area BB. Tx wires may extend to the non-display area BB along left and right sides of the display area AA (i.e., extend to the non-display area BB along a row direction X), and Rx wires may extend to the non-display area BB along upper and lower ends of the display area AA (i.e., extend to the non-display area BB along a column direction Y). Alternatively, the Tx wires may extend to the non-display area BB along the upper and lower ends of the display area AA (i.e., extend to the non-display area BB along the column direction Y), and the Rx wires may extend to the non-display area BB along the left and right sides of the display area AA (i.e., extend to the non-display area BB along the row direction X), which is not limited in the embodiments of the present disclosure.

It should be noted that the display panel 10 further includes a protective film covering the bending area B3, so that the protective film may prevent the bending area B3 from being damaged after being bent, thereby ensuring an integrity of wires in the bending area B3.

In some embodiments, as shown in FIG. 4, the display substrate 11 includes a display film layer 111, a back adhesive layer 112, and a protective layer 113 sequentially stacked on a side away from the touch layer 12.

As shown in FIG. 4, in a thickness direction, at least a part of the protective layer 113 is thinned in the bending area B3, or a whole of the protective layer 113 and the back adhesive layer 112 is thinned in the bending area B3. In this way, the bending area B3 is thinned, so that the bending radius of the bending area B3 may be reduced, and the bezel of the display panel 10 may be further reduced, thereby achieving narrow bezel of the display panel 10.

The bending area B3 may be thinned before the back adhesive layer 112 and the protective layer 113 are adhered to the backlight side of the display film layer 111, or the bending area B3 may be thinned by etching after the back adhesive layer 112 and the protective layer 113 are adhered to the backlight side of the display film layer 111, which is not limited in the embodiments of the present disclosure.

In the embodiments of the present disclosure, as shown in FIG. 1 and FIG. 3, the display panel 10 further includes a control circuit 13 including a display control module 131 (such as a PCB (printed circuit board) control circuit) and a touch module 132 (such as a touch chip TIC). The display control module 131 is electrically connected to the display wire in the binding area B4 on the display terminal B1, and the touch module 132 is electrically connected to the touch wire in the binding area B4 on the touch terminal B2.

After the bending areas B3 of the display terminal B1 and the touch terminal B2 are bent, the display control module 131 and the touch module 132 are both located on the backlight side of the display substrate 11, that is, the control circuit 13 is located on the backlight side of the display substrate 11.

Optionally, the number of display control modules 131 included in the control circuit 13 may be determined according to the number of display terminals B1 in the non-display area BB. For example, the display control modules 131 correspond to the display terminals B1 one to one, so as to simplify setting of the control circuit 13. Of course, the number of display control modules 131 may be less than the number of display terminals B1, so that a display control module 131 may be electrically connected to the display wires in a plurality of display terminals B1, which is not limited in the embodiments of the present disclosure.

When the control circuit 13 includes a plurality of display control modules 131, the plurality of display control modules 131 may be connected in series through a flexible printed circuit board, so as to simplify an electrical connection between the plurality of display control modules 131 and a control mainboard and simplify connection lines on the backlight side of the display area AA.

As shown in FIG. 3, the control circuit 13 further includes a first switching circuit 133 respectively electrically connected to the display wire and the display control module 131, and a second switching circuit 134 respectively electrically connected to the touch wire (the Tx wire and the Rx wire) and the touch module 132.

The first switching circuit 133 includes a driving chip and a connection circuit. The driving chip is electrically connected to the display wire, and is then electrically connected to the display control module 131 through the connection circuit. The driving chip and the connection circuit may be integrated on a COF circuit board simultaneously, or the connection circuit may be integrated on the FPC circuit board or the PCB circuit board separately. The second switching circuit 134 includes a connection circuit, and the second switching circuit 134 may be integrated on the FPC circuit board or the PCB circuit board separately at this time.

In the embodiments of the present disclosure, as shown in FIG. 1, the display panel 10 further includes a polarizer layer 14, an optical adhesive layer 15 and a cover plate 16 sequentially distributed on a side of the touch layer 12 away from the display substrate 11. The polarizer layer 14 covers at least the display area AA of the display substrate 11, so as to ensure a display effect of images in the display area AA. The optical adhesive layer 15 is used to adhere the cover plate 16 with the polarizer layer 14, so as to protect the display panel 10 through the cover plate 16. Furthermore, as shown in FIG. 1, the display panel 10 further includes a heat dissipation layer 17 and a support layer 18 sequentially distributed on a side of the display substrate 11 away from the touch layer 12. The heat dissipation layer 17 is used to achieve heat exchange with the display substrate 11, so as to prevent the display effect from being affected by heat generated by the display substrate 11. After the bending area B3 of the display terminal B1 and the bending area B3 of the touch terminal B2 are bent, the binding area B4 of the display terminal B1 and the binding area B4 of the touch terminal B2 are fixed on the support layer 18, so as to ensure a bending effect of the bending areas B3.

Next, the display terminal B1 included in the non-display area BB of the display substrate 11 will be explained in detail in the embodiments of the present disclosure.

In a first embodiment, as shown in FIG. 2, the non-display area BB of the display substrate 11 includes a display terminal B1 located on a side of the display area AA in the column direction Y.

A width of the display terminal B1 in the row direction X is smaller than a width of the display area AA close to the display terminal B1 in the row direction X, so that the display control module 131 may be electrically connected to the display wire through the first switching circuit 133, and after the display control module 131 is bent to a side close to the backlight side of the display area AA, the display control module 131 falls within a region enclosed by edges of the display substrate 11, thereby preventing the display control module 131 from protruding out of the edges of the display substrate 11.

Optionally, as shown in FIG. 2, the width W of the display terminal B1 in the row direction X may be not less than 70 mm and not more than 600 mm. For example, the width W of the display terminal B1 is 70 mm, 100 mm, 200 mm, 300 mm, 400 mm, 500 mm or 600 mm.

For a display panel 10 having a relatively large size, as shown in FIG. 2, the display terminal B1 includes a plurality of binding areas B4 located on a side of the bending area B3 away from the display area AA, and each of the binding areas B4 of the display terminal B1 has the display wire. In this way, through the arrangement of the plurality of binding areas B4, it is possible to prevent the display wires from being distributed in an entire region of the display terminal B1 in the row direction X, so as to reduce a size of the first switching circuit 133 in the row direction X, thus reducing an electrical connection difficulty between the display wire and the display control module 131.

In this case, for the binding areas B4 included in the display terminal B1 and the first switching circuits 133 connected to the display control module 131, the first connecting circuits 133 may correspond to the plurality of binding areas B4 one to one, so as to simplify the electrical connection between the display wires of the plurality of binding areas B4 and the display control modules 131. Of course, the number of the first switching circuits 133 may also be smaller than the number of the binding areas B4. For example, a first switching circuit 133 is connected to the display wires in at least two binding areas B4 simultaneously, and then connected to the display control module 131.

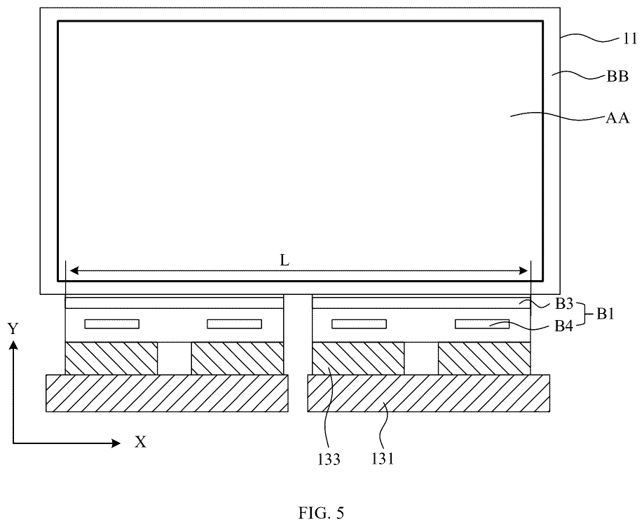

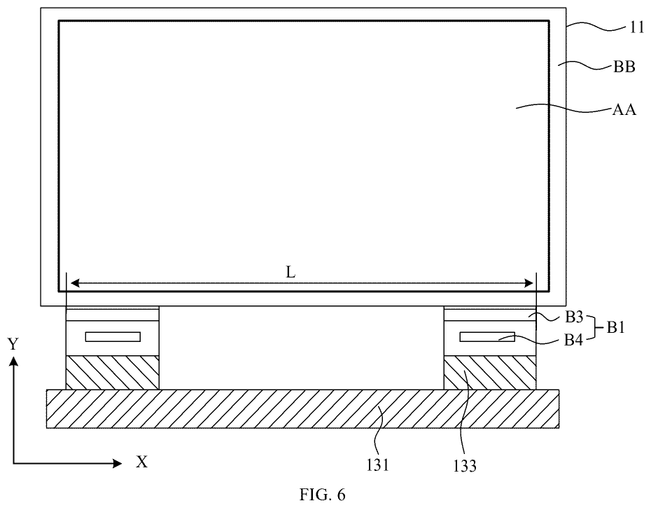

In a second embodiment, as shown in FIG. 5 or FIG. 6, the non-display area BB of the display substrate 11 includes a plurality of display terminals B1 located on a same side of the display area AA in the column direction Y and spaced apart in the row direction X. In this way, the arrangement of the plurality of display terminals B1 may reduce the width of the display terminal B1 in the row direction X, thereby facilitating bending of the bending area B3, so as to improve the bending effect of the bending area B3 on each display terminal B1.

Optionally, for the plurality of display terminals B1 included in the non-display area BB, the plurality of display terminals B1 are evenly distributed, and a distance between two adjacent display terminals B1 in the plurality of display terminals B1 is greater than 5 mm, so as to facilitate the electrical connection between the binding area B4 of each display terminal B1 and the first switching circuit 133. For example, the distance between two adjacent display terminals B1 is 5.5 mm, 6 mm, 10 mm, 15 mm or 20 mm.

Optionally, for a part of the display panel 10, the display wires of the display substrate 11 extend to positions on a same side of the display area AA in the column direction Y close to two side edges of the display region AA. In this case, as shown in FIG. 6, the non-display area BB includes two display terminals B1 connected to positions on a same side of the display area AA close to the two side edges of the display region AA, so as to achieve a span distribution of the two display terminals B1. The distance between the two display terminals B1 is greater than or equal to 30 mm, so as to facilitate other settings (such as the setting of a notch screen) of a region between the two display terminals B1 on the display substrate 11. Exemplarily, the distance between the two display terminals B1 is 30 mm, 35 mm, 40 mm, 50 mm or 60 mm.

A total length occupied by the plurality of display terminals B1 located on the same side of the display area AA in the row direction X is smaller than the width of the display area AA in the row direction X, so that the display control module 131 may be electrically connected to the display wire in the display terminal B1 through the first switching circuit 133, and after the display control module 131 is bent to the backlight side of the display area AA, the display control module 131 falls within the region enclosed by the edges of the display substrate 11, thereby preventing the display control module 131 from protruding out of the edges of the display substrate 11. In addition, as shown in FIG. 5 or FIG. 6, the total length L occupied by the plurality of display terminals B1 on the same side of the display area AA in the row direction C is not less than 70 mm and not more than 600 mm. For example, the total length L occupied by the plurality of display terminals B1 is 70 mm, 100 mm, 200 mm, 300 mm, 400 mm, 500 mm or 600 mm.

It should be noted that, as shown in FIG. 6, when the display terminal B1 includes a binding area B4, the control circuit 13 further includes a first switching circuit 133 electrically connected to the display terminal B1, so that the display wire in the binding area B4 may be electrically connected to the display control module 131 through the first switching circuit 133. As shown in FIG. 5, when the display terminal B1 includes a plurality of binding areas B4, the control circuit 13 further includes a plurality of first switching circuits 133 electrically connected to the display terminal B1, and the plurality of binding areas B4 correspond to the plurality of first switching circuits 133 one to one, so that the display wire of each binding area B4 is electrically connected to the display control module 131 through the corresponding first switching circuit 133. Of course, when the display terminal B1 includes a plurality of binding areas B4, the number of the first switching circuits 133 included in the control circuit 13 may be smaller than the number of the binding areas B4, such that the display wires in the plurality of binding areas B4 is electrically connected to the display control module 131 through a first switching circuit 133.

It should also be noted that, taking the display area AA of the display substrate 11 being rectangular as an example, the display area AA has opposite upper and lower ends (i.e., two sides of the display area AA in the column direction Y) and opposite left and right sides (i.e., two sides of the display area AA in the row direction X). For the above two embodiments, the display terminal B1 included in the non-display area BB may be located at the lower end of the display area AA. Of course, the display terminal B1 included in the non-display area BB may also be located at the upper end of the display area AA, or at the left or right side of the display area AA, which is not limited by the embodiments of the present disclosure.

Next, taking the display terminal B1 of the non-display area BB being located at the lower end of the display area AA as an example, the touch terminal B2 included in the non-display area BB will be explained in conjunction with the above two embodiments.

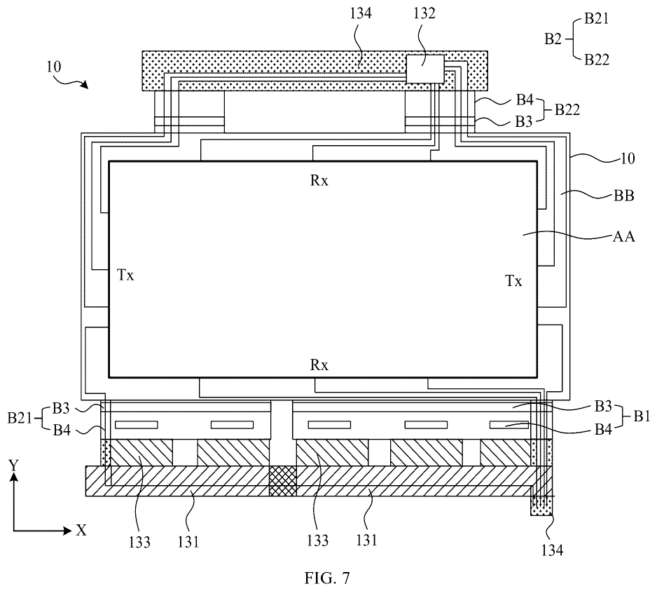

In some embodiments, as shown in FIG. 7, the non-display area BB of the display substrate 11 includes a first touch terminal B21 located on a same side of the display area AA as the display terminal B1 and located on an outermost side of the display terminal B1 in the row direction X. That is, the first touch terminal B21 included in the non-display area BB is connected to a position at the lower end of the display area AA close to an edge.

The non-display area BB of the display substrate 11 may include a first touch terminal B21 or two first touch terminals B21. When two first touch terminals B21 are included, the two first touch terminals B21 are respectively connected to positions at the lower end of the display area AA close to the two side edges. In addition, in a case that two first touch terminals B21 are included, as shown in FIG. 7, after extending out of the edge of the display area AA, the touch wire may extend to a closest first touch terminal B21, so as to effectively shorten a wire length of the touch wire at the lower end of the display area AA, effectively reduce a region occupied by the touch wire, and facilitate achieving narrow bezel of the display panel 10 at the lower end of the display area AA.

Optionally, for the first touch terminal B21 located at a position on a side of the display area AA and close to the edge, as shown in FIG. 7, the first touch terminal B21 may be integrated with an adjacent display terminal B1, thereby simplifying a structure of the display substrate 11 and improving a manufacturing efficiency of the display substrate 11. Accordingly, the second switching circuit 134 connected to the first touch terminal B21 and the first switching circuit 133 connected to the display terminal B1 may be integrated on a same FPC circuit board or PCB circuit board to simplify an arrangement of partial switching circuits.

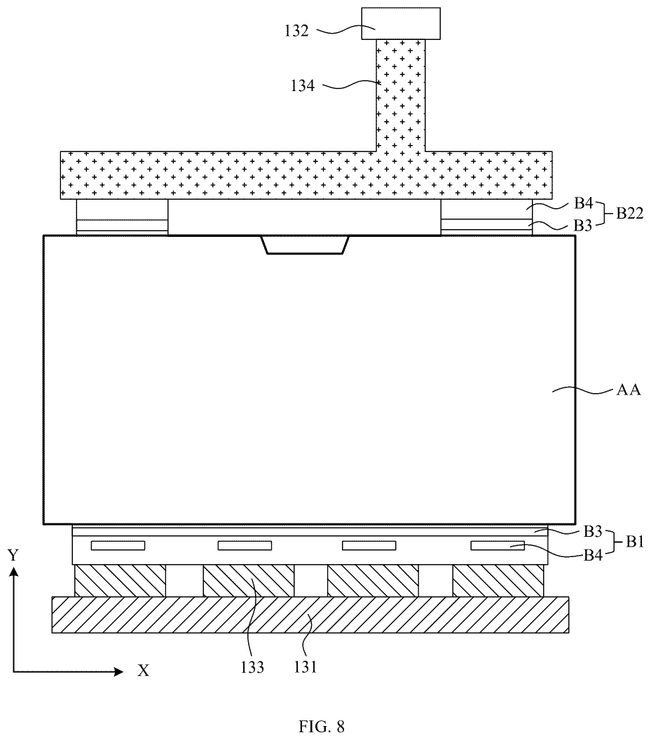

In other embodiments, as shown in FIG. 7 or FIG. 8, the non-display area BB of the display substrate 11 further includes a second touch terminal B22 located on a side of the display area AA away from the display terminal B1. That is, the second touch terminal B22 included in the non-display area BB is connected to the upper end of the display area AA. In this way, it is more convenient for the touch wires (Tx wire and Rx wire) included in the touch layer 12 to select a closest touch terminal B2 from the first touch terminal B21 and the second touch terminal B22, thereby shortening wire lengths on the left and right sides of the display area AA, effectively reducing regions occupied by the touch wires on the left and right sides of the display area AA, and facilitating achieving narrow bezel of the display panel 10 on the left and right sides of the display area AA.

The non-display area BB of the display substrate 11 may include one or more second touch terminals B22. When the non-display area BB includes one second touch terminal B22, the second touch terminal B22 is connected to a central position on a side of the display area AA away from the display terminal B1. As shown in FIG. 7 or FIG. 8, when the non-display area BB includes two second touch terminals B22, the two second touch terminals B22 are respectively connected to positions on a side of the display area AA away from the display terminal B1 close to the two side edges. Compared with the case of providing one second touch terminal B22, providing two second touch terminals B22 may further shorten a wire length of the touch wire at the upper end of the display area AA, so as to effectively reduce a region occupied by the touch wire at the upper end of the display area AA, and facilitate achieving narrow bezel of the display panel 10 at the upper end of the display area AA.

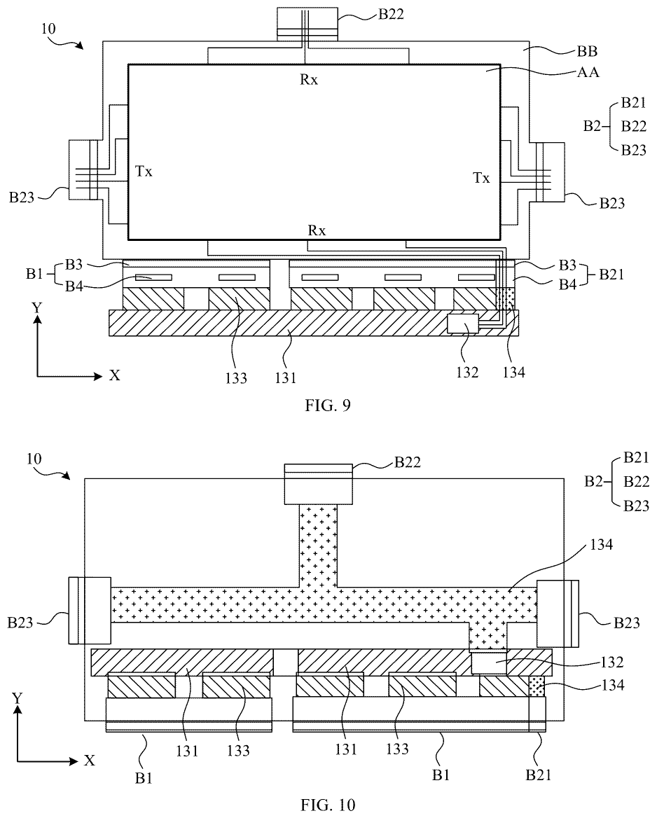

In yet other embodiments, as shown in FIG. 9, the non-display area BB of the display substrate 11 further includes a pair of third touch terminals B23 respectively located on two sides of the display area AA in the row direction X. That is, the pair of third touch terminals B23 included in the non-display area BB are respectively connected to the left and right sides of the display area AA. In this way, through the third touch terminals B23 arranged on the left and right sides of the display area AA, it is possible to prevent the touch wires extending to the left and right sides of the display area AA from further extending to the upper end and/or the lower end of the display area AA, thereby further shortening the wire lengths of the touch wires on the left and right sides of the display area AA, effectively reducing the regions occupied by the touch wires on the left and right sides of the display area AA, and facilitating achieving narrow bezel of the display panel 10 on the left and right sides of the display area AA.

The number of the third touch terminals B23 arranged on the left and right sides of the display area AA may be one or more, as long as the regions occupied by the touch wires on the left and right sides of the display area AA may be effectively reduced and the narrow bezel of the display panel 10 on the left and right sides of the display area AA may be achieved, the specific number may be determined in conjunction with the number of touch wires on the left and right sides of the display area AA.

It should be noted that for a case that the non-display area BB of the display substrate 11 includes at least two of the first touch terminal B21, the second touch terminal B22 and the third touch terminal B23 at the same time, taking the non-display area BB including the first touch terminal B21, the second touch terminal B22 and the third touch terminal B23 at the same time as an example, as shown in FIG. 10, the first touch terminal B21, the second touch terminal B22 and the third touch terminal B23 are all connected to the touch module 132 through the second switching circuit 134 on the backlight side of the display substrate 11.

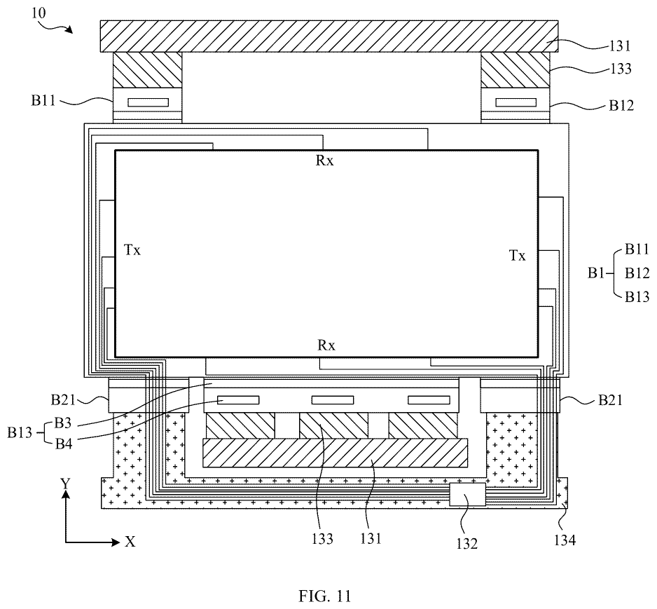

In a third embodiment, as shown in FIG. 11, the non-display area BB of the display substrate 11 includes a plurality of display terminals B1 including a first display terminal B11, a second display terminal B12 and at least one third display terminal B13. The first display terminal B11 and the second display terminal B12 are located on a same side of the display area AA in the column direction Y and spaced apart along the row direction X. The at least one third display terminal B13 is located on a side of the display area AA away from the first display terminal B11 and may be spaced apart along the row direction X. In the row direction X, at least one third display terminal B13 is located between the first display terminal B11 and the second display terminal B12.

The first display terminal B11 and the second display terminal B12 are connected to positions on a same side of the display area AA close to the two side edges, so as to achieve the span distribution of the first display terminal B11 and the second display terminal B12. A distance between the first display terminal B11 and the second display terminal B12 is not less than 30 mm, which is convenient for other settings (such as the setting of the notch screen) in a region between the first display terminal B11 and the second display terminal B12 on the display substrate 11. Exemplarily, the distance between the first display terminal B11 and the second display terminal B12 is 30 mm, 50 mm, 70 mm, 90 mm or 120 mm.

A total length occupied by the first display terminal B11 and the second display terminal B12 in the row direction X is smaller than the width of the display area AA in the row direction X, so that the display control module 131 may be electrically connected to the display wires in the first display terminal B11 and the second display terminal B12 through the first switching circuits 133, and after the display control module 131 is bent to the backlight side of the display area AA, the display control module 131 falls within the region enclosed by the edges of the display substrate 11, thereby preventing the display control module 131 from protruding out of the edges of the display substrate 11. In addition, as shown in FIG. 3, the total length L occupied by the first display terminal B11 and the second display terminal B12 in the row direction X is not less than 70 mm and not more than 600 mm. For example, the total length L occupied by the plurality of display terminals B1 is 70 mm, 100 mm, 200 mm, 300 mm, 400 mm, 500 mm or 600 mm.

The plurality of display terminals B1 in the non-display area BB on the display substrate 11 may include one or more third display terminals B13.

When the plurality of display terminals B1 include a third display terminal B13, optionally, as shown in FIG. 11, the third display terminal B13 includes a plurality of binding areas B4 located on a side of the bending area B3 away from the display area AA, and each of the plurality of binding areas B4 of the third display terminal B13 has the display wire. In this way, through the arrangement of the plurality of binding areas B4, it is possible to prevent the display wires from being distributed in an entire edge region of the display terminals B1 in the row direction X, so as to reduce the electrical connection difficulty between the display wire and the display control module 131.

At this time, as shown in FIG. 11, for the first switching circuit 133 connecting the display wire in the third display terminal B13 with the display control module 131, the first switching circuit 133 may correspond to the plurality of binding areas B4 one to one, so as to simplify the electrical connection between the display wires in the binding areas B4 and the display control module 131. Of course, the number of the first switching circuits 133 may also be smaller than the number of the binding areas B4, for example, a first switching circuit 133 is connected to the display control module 131 through the display wires in at least two binding areas B4.

When the plurality of display terminals B1 include a plurality of third display terminals B13, the plurality of third display terminals B13 are spaced apart, and a distance between two adjacent third display terminals B13 among the plurality of third display terminals B13 is greater than 5 mm, so that each third display terminal B13 is electrically connected to the first switching circuit 133. For example, the distance between two adjacent third display terminals B13 is 5.5 mm, 6 mm, 10 mm, 15 mm or 20 mm.

It should be noted that, taking the display area AA of the display substrate 11 being rectangular as an example, the display area AA has opposite upper and lower ends, and opposite left and right sides. For the third embodiment, the first display terminal B11 and the second display terminal B12 may be located at the upper end of the display area AA, and the at least one third display terminal B13 is located at the lower end of the display area AA. Of course, the first display terminal B11 and the second display terminal B12 may also be located on the left side of the display area AA, and the at least one third display terminal B13 may be located on the right side of the display area AA, which is not limited in the embodiments of the present disclosure.

Next, taking the first display terminal B11 and the second display terminal B12 of the non-display area BB being located at the upper end of the display area AA and the at least one third display terminal B13 being located at the lower end of the display area AA as an example, the touch terminal B2 included in the non-display area BB will be explained in detail in conjunction with the above third embodiment.

In some embodiments, as shown in FIG. 11, the non-display area BB of the display substrate 11 includes a pair of first touch terminals B21 located on a same side of the display area AA as the third display terminal B13, and the pair of first touch terminals B21 are respectively located on two sides of the at least one third display terminal B13 in the row direction X. That is, the pair of first touch terminals B21 included in the non-display area BB are respectively connected to positions at the lower end of the display area AA close to the two side edges.

Through the arrangement of a pair of first touch terminals B21, the touch wire at the lower end of the display area AA may extend to a closest first touch terminal B21, so as to effectively shorten the wire length of the touch wire at the lower end of the display area AA, effectively reduce the region occupied by the touch wire, and facilitating achieving narrow bezel of the display panel 10 at the lower end of the display area AA.

In addition, the first touch terminal B21 and the third display terminal B13 may be spaced apart, or may be arranged in an integrated structure. When the first touch terminal B21 and the third display terminal B13 are spaced apart, a distance between the first touch terminal B21 and the third display terminal B13 is greater than 5 mm, so that the first touch terminal B21 and the third display terminal B13 may be electrically connected to the corresponding second switching circuit 134 and first switching circuit 133, respectively. For example, the distance between the first touch terminal B21 and the third display terminal B13 is 5.5 mm, 6 mm, 10 mm, 15 mm or 20 mm.

When the first touch terminal B21 and the third display terminal B13 are integrated, the structure of the display substrate 11 may be simplified and the manufacturing efficiency of the display substrate 11 may be improved. Accordingly, the second switching circuit 134 connected to the first touch terminal B21 and the first switching circuit 133 connected to the third display terminal B13 may be integrated on a same FPC circuit board or PCB circuit board to simplify the arrangement of partial switching circuits.

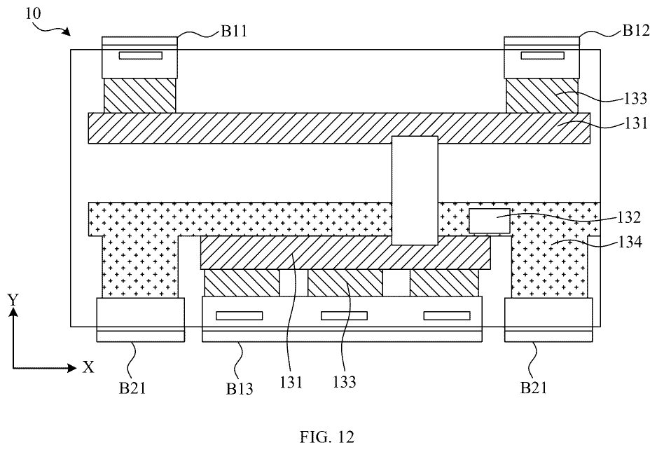

It should be noted that for the second switching circuit 134 of a pair of electrically connected first touch terminals B21, a gap may be formed between the first display terminal B11 and the third display terminal B13. At this time, as shown in FIG. 12, the electrical connection between the display control module 131 connected to the first display terminal B11 and the display control module 131 connected to the third display terminal B13 may be achieved through a jumper circuit.

In other embodiments, the non-display area BB of the display substrate 11 further includes a pair of third touch terminals B23 respectively located on two sides of the display area AA in the row direction X. That is, the pair of third touch terminals B23 included in the non-display area BB are respectively connected to the left and right sides of the display area AA. In this way, through the third touch terminals B23 arranged on the left and right sides of the display area AA, it is possible to prevent the touch wires extending to the left and right sides of the display area AA from further extending to the upper end and/or the lower end of the display area AA, thereby shortening the wire lengths of the touch wires on the left and right sides of the display area AA, effectively reducing the regions occupied by the touch wires on the left and right sides of the display area AA, and facilitating achieving narrow bezel of the display panel 10 on the left and right sides of the display area AA.

The number of the third touch terminals B23 arranged on the left and right sides of the display area AA may be one or more. As long as the regions occupied by the touch wires on the left and right sides of the display area AA may be effectively reduced, and narrow bezel of the display panel 10 on the left and right sides of the display area AA may be achieved, the specific number may be determined in conjunction with the number of the touch wires on the left and right sides of the display area AA.

The embodiments of the present disclosure further provide a method of manufacturing the display panel, which is used for manufacturing the display panel described in the above embodiments. The method includes step S110 to step S130.

Step S110, a display substrate having a display area and a non-display area at a periphery of the display area is manufactured. The non-display area includes a display terminal and a touch terminal, each of the display terminal and the touch terminal includes a bending area and a binding area, the bending area is respectively connected to the display area and the binding area, and the display area has a display wire extending to the binding area of the display terminal.

Step S120, a touch layer is manufactured on a light emitting side of the display substrate. The touch layer includes a touch wire extending to the binding area of the touch terminal.

Step S130, a control circuit is provided. The control circuit includes a display control module and a touch module, after the bending area is bent such that the binding area is located on a backlight side of the display area, and then at a backlight side of the display substrate, the display control module is electrically connected to the display wire, and the touch module is electrically connected to the touch wire.

In the embodiments of the present disclosure, the display terminal and the touch terminal located in the non-display area are directly arranged on the display substrate included in the display panel, so that the binding area is bent to the backlight side of the display area based on the bending areas on the display terminal and the touch terminal, thereby reducing the bending radius of the display terminal, effectively reducing the bezel of the display panel and achieving the narrow bezel of the display panel.

In the above step S110, reference may be made to related technologies for the manufacturing processes of the display terminal and touch terminal included in the non-display area, and the specific manufacturing of the display terminal and touch terminal may be determined in conjunction with the number and distribution positions of the display terminal and the touch terminal described in the above embodiments, which is not limited in the embodiments of the present disclosure. In addition, reference may be made to the above embodiments for the thinning of the bending area.

It should be noted that although various steps of the method of manufacturing the display panel in the present disclosure are described in a specific order, this does not require or imply that these steps must be executed in the specific order, or that all the steps shown must be executed to achieve the desired result. Additionally or alternatively, some steps may be omitted, a plurality of steps may be combined into one step for execution, and/or one step may be decomposed into a plurality of steps for execution.

The embodiments of the present disclosure further provide a display device. The display device includes a control mainboard and the display panel described in the above embodiments. The display control module and the touch module included in the control circuit are electrically connected to the control mainboard. In this way, the touch operation and image display of the display device may be achieved by controlling the mainboard. In addition, based on the bending manner of the display panel, the bezel of the display device is effectively reduced, and a high screen ratio of the display device is achieved.

Those skilled in the art may easily conceive of other embodiments of the present disclosure after considering the specification and practicing the present disclosure. The present disclosure is intended to cover any variations, uses or adaptive changes of the present disclosure. These variations, uses or adaptive changes follow the general principles of the present disclosure and include common knowledge or common technical means in the art that are not disclosed in the present disclosure. The specification and the embodiments are regarded as exemplary only, and the true scope and spirit of the present disclosure are indicated by the appended claims.

1. A display panel, comprising:
a display substrate comprising a display area and a non-display area located at a periphery of the display area, wherein the non-display area comprises a display terminal and a touch terminal, each of the display terminal and the touch terminal comprises a bending area and a binding area, the bending area is respectively connected to the display area and the binding area, the binding area is located on a backlight side of the display area after the bending area is bent, and the display area comprises a display wire extending to the binding area of the display terminal;
a touch layer located on a light emitting side of the display substrate and comprising a touch wire located in the display area and extending to the binding area of the touch terminal; and
a control circuit located on the backlight side of the display substrate and comprising a display control module electrically connected to the display wire and a touch module electrically connected to the touch wire.

2. The display panel according to claim 1, wherein,
the non-display area comprises one display terminal located on a side of the display area in a column direction; and
the display terminal comprises a plurality of binding areas located on a side of the bending area away from the display area, and each of the plurality of binding areas of the display terminal comprises the display wire.

3. The display panel according to claim 2, wherein a width of the display terminal in a row direction is not less than 70 mm and not more than 600 mm.

4. The display panel according to claim 1, wherein the non-display area comprises a plurality of display terminals located on a same side of the display area in a column direction and spaced apart in a row direction.

5. The display panel according to claim 4, wherein a distance between adjacent display terminals is greater than 5 mm.

6. The display panel according to claim 2, wherein the non-display area comprises a first touch terminal located on a same side of the display area as the display terminal, and the first touch terminal is located on an outermost side of the display terminal in a row direction.

7. The display panel according to claim 6, wherein the first touch terminal is integrated with the adjacent display terminal.

8. The display panel according to claim 6, wherein the non-display area further comprises a second touch terminal located on a side of the display area away from the display terminal.

9. The display panel according to claim 8, wherein the non-display area further comprises a pair of third touch terminals respectively located on two sides of the display area in the row direction.

10. The display panel according to claim 1, wherein,
the non-display area comprises a plurality of display terminals, and the plurality of display terminals comprise a first display terminal, a second display terminal and at least one third display terminal; and
the first display terminal and the second display terminal are located on a same side of the display area in a column direction and spaced apart in a row direction; the at least one third display terminal is located on a side of the display area away from the first display terminal and spaced apart in the row direction, and each of the at least one third display terminal is located between the first display terminal and the second display terminal in the row direction.

11. The display panel according to claim 10, wherein a distance between the first display terminal and the second display terminal is not less than 30 mm.

12. The display panel according to claim 10, wherein the non-display area comprises a pair of first touch terminals located on a same side of the display area as the at least one third display terminal, and the pair of first touch terminals are respectively located on two sides of the at least one third display terminal in the row direction.

13. The display panel according to claimed in claim 12, wherein the non-display area further comprises a pair of third touch terminals respectively located on two sides of the display area in the row direction.

14. The display panel according to claim 1, wherein,
the control circuit further comprises a first switching circuit and a second switching circuit; and
the first switching circuit is respectively electrically connected to the display wire and the display control module, and the second switching circuit is respectively electrically connected to the touch wire and the touch module.

15. The display panel according to claim 1, wherein,
the display substrate comprises a display film layer, a back adhesive layer and a protective layer sequentially stacked in a direction away from the touch layer; and
at least a part of the protective layer is thinned in the bending area in a thickness direction, or a whole of the protective layer and the back adhesive layer is thinned in the bending area.

16. A method of manufacturing a display panel, comprising:
manufacturing a display substrate comprising a display area and a non-display area located at a periphery of the display area, wherein the non-display area comprises a display terminal and a touch terminal, each of the display terminal and the touch terminal comprises a bending area and a binding area, the bending area is respectively connected to the display area and the binding area, and the display area comprises a display wire extending to the binding area of the display terminal;
manufacturing a touch layer on a light emitting side of the display substrate, wherein the touch layer comprises a touch wire extending to the binding area of the touch terminal; and
providing a control circuit comprising a display control module and a touch module, wherein the bending area is bent such that the binding area is located on a backlight side of the display area, and on the backlight side of the display substrate, the display control module is electrically connected to the display wire, and the touch module is electrically connected to the touch wire.

17. A display device, comprising a control mainboard and the display panel according to claim 1, wherein the display control module and the touch module are electrically connected to the control mainboard.

18. The display panel according to claim 3, wherein the non-display area comprises a first touch terminal located on a same side of the display area as the display terminal, and the first touch terminal is located on an outermost side of the display terminal in a row direction.

19. The display panel according to claim 4, wherein the non-display area comprises a first touch terminal located on a same side of the display area as the display terminal, and the first touch terminal is located on an outermost side of the display terminal in a row direction.

20. The display panel according to claim 5, wherein the non-display area comprises a first touch terminal located on a same side of the display area as the display terminal, and the first touch terminal is located on an outermost side of the display terminal in a row direction.
